(19) United States
(12) Patent Application Publication
(10) Pub. No.: US 2003/0025141 A1
(43) Pub. Date: Feb. 6, 2003

(54) Arrangement of trenches in a semiconductor substrate, in particular for trench capacitors

(76) Inventor: Wolfgang Grimm, Stockdorf (DE)

Correspondence Address: JENKINS & WILSON, PA, 3100 TOWER BLVD, SUITE 1400, DURHAM, NC, 27707, US

(21) Appl. No.: 10/199,450

(22) Filed: Jul. 19, 2002

(30) Foreign Application Priority Data
Jul. 23, 2001 (DE) 10134955.6-33

(51) Int. Cl. H01L 31/119

(52) U.S. Cl. 257/301

(57) ABSTRACT

Arrangement of trenches in a semiconductor substrate, in particular for trench capacitors

The present invention provides an arrangement of trenches in a semiconductor substrate, in particular for trench capacitors, having a plurality of regularly arranged trenches (G1′-G4′; G1″-G4″) which extend in a depth direction (T) proceeding from a surface (O) of the semiconductor substrate; the trenches (G1′-G4′; G1″-G4″) having in each case an at least one widened region in the depth direction (T); and widened regions of adjacent trenches (G1′-G4′; G1″-G4″) are offset relative to one another in the depth direction.

Arrangement of trenches in a semiconductor substrate, in particular for trench capacitors

The present invention relates to an arrangement of trenches in a semiconductor substrate, in particular for trench capacitors, having a plurality of regularly arranged trenches which extend in a depth direction proceeding from a surface of the semiconductor substrate, the trenches having in each case an at least one widened region in the depth direction.

Although applicable, in principle, to any desired trenches in a semiconductor substrate, the present invention and the problems on which it is based will be explained below with regard to a trench capacitor used in a DRAM memory cell. Such memory cells are used in integrated circuits (ICs), such as, for example, random access memories (RAMs), dynamic RAMs (DRAMs), synchronous DRAMs (SDRAMs), static RAMs (SRAMs) and read-only memories (ROMs). Other integrated circuits contain logic devices, such as, for example, programmable logic arrays (PLAs), application-specific ICs (ASICs), mixed logic/memory ICs (embedded DRAMs) or other circuit devices. It is usual for a multiplicity of ICs to be fabricated in parallel on a semiconductor substrate, such as, for example, a silicon wafer. After processing, the wafer is divided in order to separate the ICs into a multiplicity of individual chips. The chips are then packaged into end products, for example for use in consumer products such as, for example, computer systems, cellular telephones, personal digital assistants (PDAs) and further products. For discussion purposes, the invention will be described with regard to the formation of an individual memory cell.

Integrated circuits (ICs) or chips use capacitors for the purpose of storing charge. One example of an IC which uses capacitors to store charges is a memory IC, such as, for example, a chip for a dynamic read/write memory with random access (DRAM) . The charge state (“0” or “1”) in the capacitor represents a data bit in this case.

A DRAM chip contains a matrix of memory cells which are connected up in the form of rows and columns. The row connections are usually referred to as word lines and the column connections as bit lines. The reading of data from the memory cells or the writing of data to the memory cells is realized by activating suitable word lines and bit lines.

A DRAM memory cell usually contains a transistor connected to a capacitor. The transistor contains two diffusion regions separated by a channel above which a gate is arranged. Depending on the direction of the current flow, one diffusion region is referred to as the drain and the other as the source. The designations “drain” and “source” are used mutually interchangeably here with regard to the diffusion regions. The gates are connected to a word line, and one of the diffusion regions is connected to a bit line. The other diffusion region is connected to the capacitor. The application of a suitable voltage to the gate switches the transistor on and enables a current flow between the diffusion regions through the channel in order thus to form a connection between the capacitor and the bit line. The switching-off of the transistor disconnects this connection by interrupting the current flow through the channel.

The charge stored in the capacitor decreases with time on account of an inherent leakage current. Before the charge has decreased to an indefinite level (below a threshold value), the storage capacitor must be refreshed.

Ongoing endeavors to reduce the size of storage devices foster the design of DRAMs having a greater density and a smaller characteristic size, that is to say a smaller memory cell area. In order to fabricate memory cells which occupy a smaller surface region, smaller components, for example capacitors, are used. However, the use of smaller capacitors results in a reduced storage capacitance, which, in turn, can adversely affect the functionality and usability of the storage device. For example, sense amplifiers require a sufficient signal level for reliable read-out of the information in the memory cells. The ratio of the storage capacitance to the bit line capacitance is critical in determining the signal level. If the storage capacitance becomes too small, this ratio may be too small to generate a sufficient signal. Likewise, a smaller storage capacitance requires a higher refresh frequency.

One type of capacitor usually used in DRAMs is a trench capacitor. A trench capacitor has a three-dimensional structure formed in the silicon substrate. An increase in the volume or the capacitance of the trench capacitor can be achieved by etching more deeply into the substrate. In this case, the increase in the capacitance of the trench capacitor does not have the effect of enlarging the surface occupied by the memory cell.

A customary trench capacitor contains a trench etched into the substrate. This trench is typically filled with p⁺- or n⁺-doped polysilicon, which serves as one capacitor electrode (also referred to as storage capacitor). The second capacitor electrode is the substrate or a “buried plate”. A capacitor dielectric containing e.g. nitride is usually used to insulate the two capacitor electrodes.

A dielectric collar (preferably an oxide region) is produced in the upper region of the trench in order to prevent a leakage current or to insulate the upper part of the capacitor.

The capacitor dielectric in the upper region of the trench, where the collar is to be formed, is usually removed before said collar is formed, since this upper part of the capacitor dielectric is a hindrance for subsequent process steps.

In order to further increase the storage density for future memory technology generations, the feature size is reduced from generation to generation. The ever decreasing capacitor area and the decreasing capacitor capacitance thus caused lead to problems. Therefore, it is an important object to keep the capacitor capacitance at least constant despite a smaller feature size. This can be achieved inter alia by increasing the surface charge density of the storage capacitor.

Previously, this problem has been solved on the one hand by enlarging the available capacitor area for a predetermined feature size, for example by widening the trench (“wet bottle”) below the collar. The trenches are usually widened bulbously in the lower trench region in order to compensate for the reduction of the trench capacitance brought about by the increasing miniaturization.

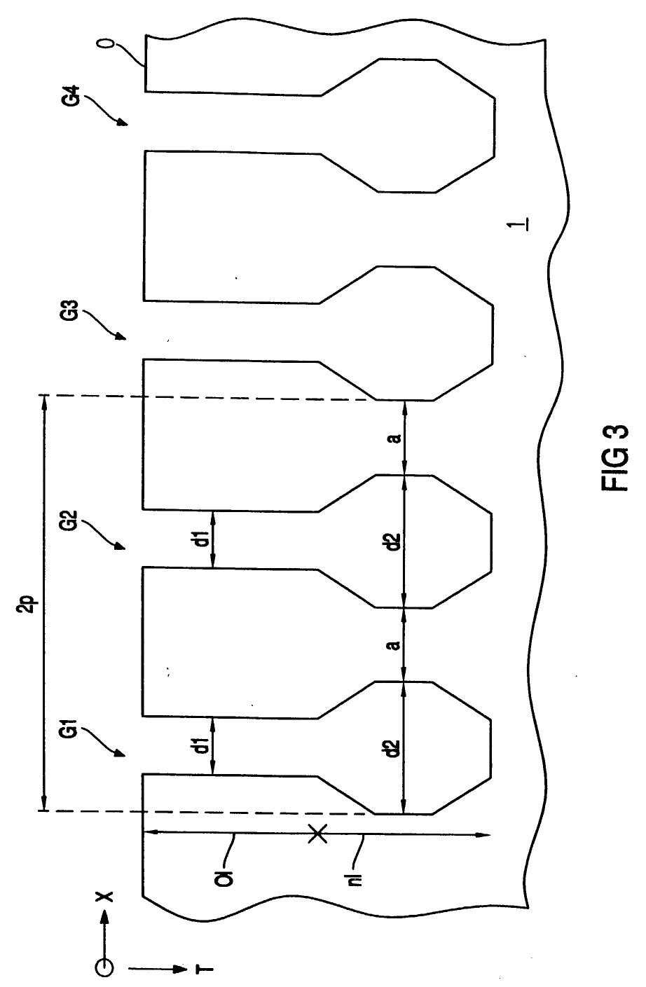

FIG. 3 shows a customary arrangement of trenches in a semiconductor substrate for trench capacitors.

In accordance with FIG. 3, four trenches G1-G4 are provided in a semiconductor substrate 1, for example a silicon substrate, which trenches extend in the depth direction proceeding from the surface O of the semiconductor substrate. The trenches G1-G4 are strung together with a minimum distance a in the x direction, the minimum distance a resulting from the respective fabrication technology. The trenches themselves all have the same depth profile in the depth direction, namely, proceeding from the surface O, a first, smaller diameter d1 over a first length o1. Adjoining that, the trenches G1-G4 have a widened portion with a maximum diameter d2 over a second length u1.

As can clearly be discerned from FIG. 3, the packing density in the customary case is:

P=0.5*(2*d2+2*a) (1)

It is an object of the present invention to provide an improved arrangement of trenches in a semiconductor substrate which enables a greater packing density.

According to the invention, this object is achieved by means of the arrangement of trenches in a semiconductor substrate as specified in claim 1.

The invention's arrangement of trenches in a semiconductor substrate has the advantage over the known solution approaches that a higher packing density can be obtained by virtue of the fact that widened regions of adjacent trenches are offset relative to one another in the depth direction.

The respective subclaims relate to preferred developments.

In accordance with one preferred development, the trenches form a first group with a first depth profile and a second group with a second depth profile, which are arranged alternately at least along a first direction.

In accordance with a further preferred development, the trenches are arranged alternately in matrix form along a first and second direction.

In accordance with a further preferred development, the first depth profile, proceeding from the surface in the depth direction, has a first diameter on a first length and has the widened region with a maximum second diameter on an adjoining second length, the second diameter being greater than the first diameter.

In accordance with a further preferred development, the second depth profile, proceeding from the surface in the depth direction, has the widened region with the maximum second diameter on a first length and has the first diameter on an adjoining second length.

In accordance with a further preferred development, the second depth profile, proceeding from the surface in the depth direction, has the first diameter on a first length, has the widened region with the maximum second diameter on an adjoining second length and has the first diameter on an adjoining third length.

In accordance with a further preferred development, the widened regions of adjacent trenches are offset relative to one another in the depth direction in such a way that a minimum lateral distance a can be provided between adjacent trenches, which is connected with a packing density P′ given by P′=0.5*(d1+d2+a′) where d1 is the first diameter and d2 is the second diameter.

In accordance with a further preferred development, the volume and the volume proportion of the widened region are essentially the same in all the trenches.

Exemplary embodiments of the present invention are illustrated in the drawings and are explained in more detail in the description below.

In the figures:

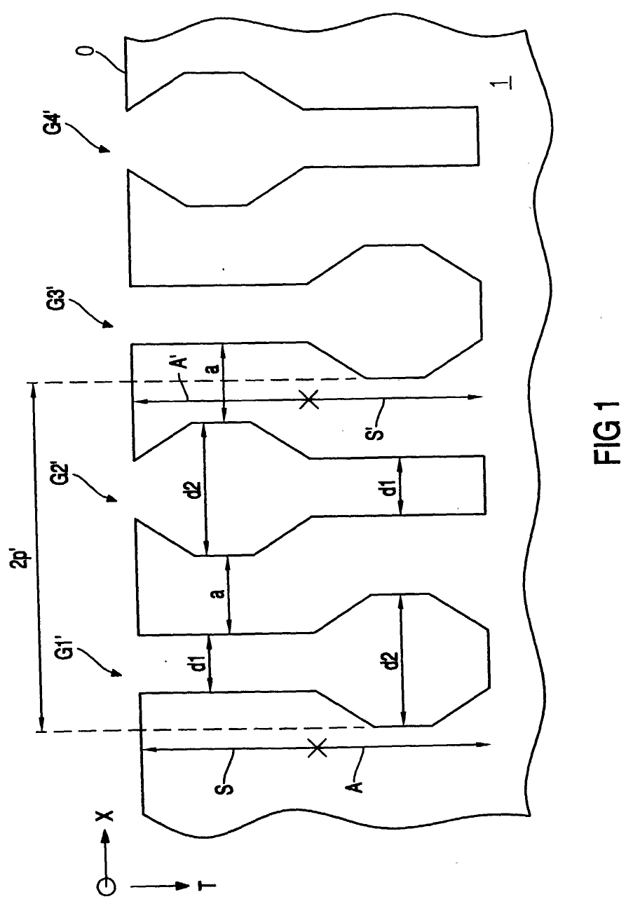

FIG. 1 shows an arrangement of trenches in a semiconductor substrate for trench capacitors in accordance with a first embodiment of the present invention;

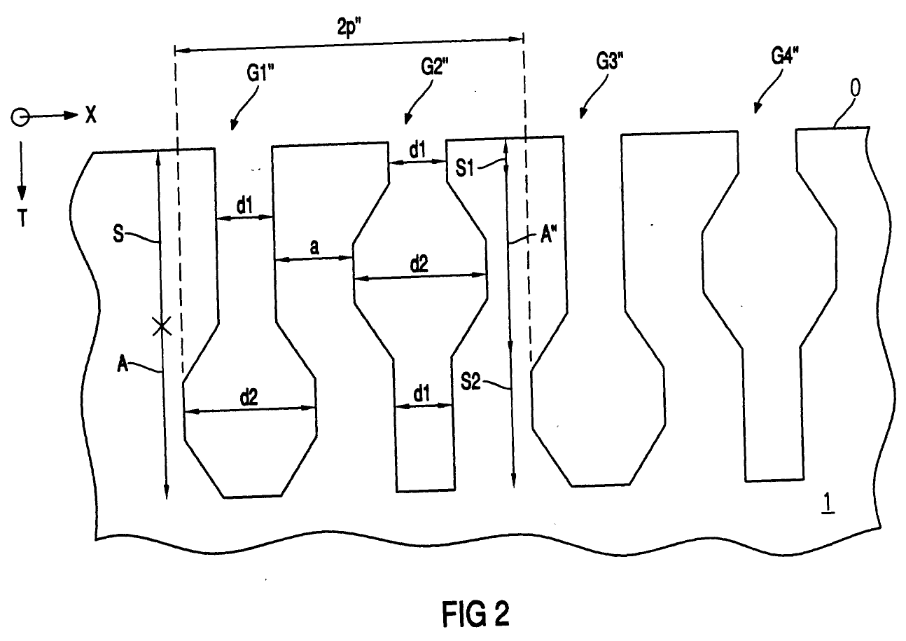

FIG. 2 shows an arrangement of trenches in a semiconductor substrate for trench capacitors in accordance with a second embodiment of the present invention; and

FIG. 3 shows a customary arrangement of trenches in a semiconductor substrate for trench capacitors.

In the figures, identical reference symbols designate identical or functionally identical elements.

FIG. 1 shows an arrangement of trenches in a semiconductor substrate for trench capacitors in accordance with a first embodiment of the present invention.

In accordance with FIG. 1, four trenches G1′-G4′ are likewise provided in the semiconductor substrate 1, said trenches being strung together serially in the x direction. In this embodiment, in contrast to the known prior art, there are two different groups of trenches, namely a first group with the trenches G1′and G3′ and a second group with the trenches G2′ and G4′. The trenches G1′and G3′ of the first group are arranged as in the prior art in such a way that, proceeding from the substrate surface O, firstly a first diameter d1 is present over a length S and, adjoining that, a widened portion with a maximum second diameter d2 is present over a second length A.

The trenches of the second group G2′, G4′ are rotated, as it were, relative to the trenches G1′, G3′ of the first group. Their widened region begins directly at the surface O and extends over a first length A′, this being adjoined by the narrower region with the diameter d1 over a second length S′. In the present case, the length S has the same magnitude as the length A′ and the length A has the same magnitude as the length S′. Such an arrangement makes it possible to achieve a greater packing density, which is given as follows in the present case:

P′0.5*(d1+d2+2*a) (2)

Consequently, the packing density is increased by approximately 20% in the case depicted. In respect of the functionality, the geometry according to the invention and the customary geometry are equivalent in so far as both the volume of the trenches and the volume proportion of the widened region of the two groups can be configured identically.

FIG. 2 shows an arrangement of trenches in a semiconductor substrate for trench capacitors in accordance with a second embodiment of the present invention.

The second embodiment illustrated in FIG. 2 takes account of the fact that it may be technologically difficult or unfavorable, under certain circumstances, to allow the widened region to begin directly at the surface O of the semiconductor substrate 1. Accordingly, in the case of the second embodiment, which, incidentally, has the same packing density as the first embodiment, in the trenches of the second group G2″, G4″ there is provided, above the widened region proceeding from the surface O, an additional region with the first diameter d1 over a length S1. That is adjoined by the widened region over the length A″, and that is again adjoined by the second region with the diameter d1 over a length S2. In order to provide identical conditions with regard to the trench volume, the lengths S1 and S2 can be provided in such a way that the following holds true:

S=S1+S2 (3)

Although the present invention has been described above using a preferred exemplary embodiment, it is not restricted thereto, but rather can be modified in diverse ways.

It is also possible, of course, to provide trenches having a plurality of widened regions and narrower regions which are correspondingly offset relative to one another.

1. Arrangement of trenches in a semiconductor substrate, in particular for trench capacitors, having:
a plurality of regularly arranged trenches (G1′-G4′; G1″-G4″) which extend in a depth direction (T) proceeding from a surface (O) of the semiconductor substrate;
the trenches (G1′-G4′; G1″-G4″) having in each case an at least one widened region in the depth direction (T);
characterized
in that widened regions of adjacent trenches (G1′-G4′; G1″-G4″) are offset relative to one another in the depth direction.

2. Arrangement according to claim 1,
characterized
in that the trenches (G1′-G4′; G1″-G4″) form a first group (G1′, G3′; G1″, G3″) with a first depth profile and a second group (G2′, G4′; G2″, G4″) with a second depth profile, which are arranged alternately at least along a first direction (x).

3. Arrangement according to claim 2,
characterized
in that the trenches (G1′-G4′; G1″-G4″) are arranged alternately in matrix form along a first and second direction.

4. Arrangement according to claim 2,
characterized
in that the first depth profile, proceeding from the surface (O) in the depth direction, has a first diameter (d1) on a first length (S) and has the widened region with a maximum second diameter (d2) on an adjoining second length (A), the second diameter (d2) being greater than the first diameter (d1).

5. Arrangement according to claim 4,
characterized
in that the second depth profile, proceeding from the surface (O) in the depth direction, has the widened region with the maximum second diameter (d2) on a first length (A′) and has the first diameter (d1) on an adjoining second length (S′).

6. Arrangement according to claim 4,
characterized
in that the second depth profile, proceeding from the surface (O) in the depth direction, has the first diameter (d1) on a first length (S1), has the widened region with the maximum second diameter (d2) on an adjoining second length (A″) and has the first diameter (d1) on an adjoining third length (S2).

7. Arrangement according to claim 5 or 6,
characterized
in that the widened regions of adjacent trenches (G1′-G4′; G1″-G4″) are offset relative to one another in the depth direction in such a way that a minimum lateral distance a′ can be provided between adjacent trenches (G1′-G4′; G1″-G4″), which is connected with a packing density P′ given by P′=0.5*(d1+d2+a′) where d1 is the first diameter and d2 is the second diameter.

8. Arrangement according to one of the preceding claims,
characterized
in that the volume and the volume proportion of the widened region are essentially the same in all the trenches (G1′-G4′; G1″-G4″).
